(19) United States
(12) Patent Application Publication
(10) Pub. No.: US 2025/0389787 A1
(43) Pub. Date: Dec. 25, 2025

(54) METHODS AND APPARATUSES FOR DE-ENERGIZED CIRCUIT TESTING BASED ON DRIVER-INDUCED ELECTRICAL QUANTITY

(71) Applicants: Marco LISERRE, Itzehoe (DE); Arkadeb SENGUPTA, Kiel (DE); Thiago ANTONIO PEREIRA, Itzehoe (DE)

(72) Inventors: Marco LISERRE, Itzehoe (DE); Arkadeb SENGUPTA, Kiel (DE); Thiago ANTONIO PEREIRA, Itzehoe (DE)

(21) Appl. No.: 19/248,865

(22) Filed: Jun. 25, 2025

(30) Foreign Application Priority Data
Jun. 25, 2024 (DE) 10 2024 117 933.3

(51) Int. Cl. G01R 31/40; G01R 19/165

(52) U.S. Cl. CPC G01R 31/40; G01R 19/16538

(57) ABSTRACT

A method and an apparatus for testing a circuit is described. The circuit includes two terminals, a capacitor coupled between the two terminals and a plurality of serially connected transistors coupled in parallel with the capacitor between the two terminals. The method includes complementarily driving the plurality of serially connected transistors with the two terminals being in a de-energized state, detecting an electrical quantity of the circuit, and determining, using the electrical quantity, whether or not the circuit is healthy.

### CROSS-REFERENCE TO RELATED APPLICATION

This application claims priority from German Patent Application No. DE 10 2024 117 933.3, which was filed on Jun. 25, 2024, and is incorporated herein in its entirety by reference.

Embodiments according to the invention comprise methods and apparatuses for de-energized circuit testing based on a driver-induced electrical quantity. Further embodiments according to the invention comprise methods and related apparatuses to detect and locate failures of insulated-gate power semiconductor devices in a power electronic converter, prior to the energization of the converter. Yet further embodiments according to the invention comprise methods and apparatuses for driver-induced residual DC link voltage-based detection of switching cell failure.

### BACKGROUND OF THE INVENTION

Existing fault diagnostic methods for power converter systems require the energization of the power circuit or complex sensing systems. Hence, such conventional approaches cause a significant test and hardware complexity, in particular for cascaded systems having a large number of modular cells.

Therefore, it is desired to get a concept, which achieves a better compromise between an effectiveness of a circuit testing, for example with regard to different modes of failure, a hardware complexity and computational complexity for the test execution and test evaluation, as well as a reliability, a time effort and hence an efficiency of the testing.

This is achieved by the subject matter of the independent claims of the present application. Further embodiments according to the invention are defined by the subject matter of the dependent claims of the present application.

### SUMMARY

An embodiment may have a method for testing a circuit, the circuit comprising two terminals, a capacitor coupled between the two terminals and a plurality of serially connected transistors coupled in parallel with the capacitor between the two terminals, the method comprising: complementarily driving the plurality of serially connected transistors with the two terminals being in a de-energized state, detecting an electrical quantity of the circuit, and determining, using the electrical quantity, whether or not the circuit is healthy.

Another embodiment may have an apparatus for testing a circuit, the circuit comprising two terminals, a capacitor coupled between the two terminals and a plurality of serially connected transistors coupled in parallel with the capacitor between the two terminals, the apparatus comprising: a driver circuit connectable to the plurality of serially connected transistors for complementarily driving the plurality of serially connected transistors of the circuit, a measurement device for detecting an electrical quantity of the circuit with the two terminals being in a de-energized state and with the plurality of serially connected transistors of the circuit being driven complementarily, and a signal processing circuit coupled to the measurement device for determining, using the electrical quantity, whether or not the circuit is healthy.

Embodiments according to the invention comprise a method for testing a circuit, the circuit comprising two terminals, a capacitor coupled between the two terminals and a plurality of serially connected transistors coupled in parallel with the capacitor between the two terminals. The method comprises complementarily driving the plurality of serially connected transistors with the two terminals being in a de-energized state, detecting an electrical quantity of the circuit, and determining, using the electrical quantity, whether or not the circuit is healthy.

Optionally, detecting the electrical quantity may comprise one or more of the following: detecting a voltage across the capacitor, e.g., by connecting a voltage measurement device across the two terminals, detecting a voltage across the terminals and/or detecting a voltage across one or more individual elements in the circuit (e.g. across one or more of the transistors, e.g. across a resistor implemented in the circuit).

The circuit may comprise or may, for example, be a switching cell, such as a two-level switching cell. The terminals may, for example, be DC bus voltage terminals and the transistors may, for example, be insulated-gate transistors, e.g. MOSFETs and/or IGBTs.

As an example, load paths, e.g. collector-emitter paths, e.g. drain-source paths (e.g. forming a power-loop of the circuit) of the two transistors may be coupled between the first and second terminal and in parallel to the capacitor.

The driving of the plurality of serially connected transistors may, for example, be performed with complementary gate signals, e.g. complementary pulse signals, e.g. having a dead time between complementary signal portions, in order to induce a signal (e.g. a voltage signal, e.g. v_{f}, e.g. a current signal, e.g. a gate driver-induced residual voltage, e.g. GIRV), in a load path of the circuit (e.g. power-loop of the circuit), while the first and second terminal are in a de-energized state.

The de-energized state may, for example, be a state in which the power-loop of the circuit is not energized externally (e.g. only energized by parasitic or coupling effects from a gate loop stimulus). The de-energized state may be a state in which the terminals are, for example, not provided with an external voltage, in which the terminals are, for example, not provided with an external test signal, in which the terminals are, for example, not provided with an external load path signal and/or in which the terminals are, for example, not provided with an external load signal.

The voltage across the capacitor may, for example, be an accumulated voltage induced in the power-loop or load path of the circuit by the complementary drive signals of the transistors, hence, for example, from the gate-loop of the circuit.

The inventors recognized that by complementarily driving the transistors, a voltage may be induced, e.g. accumulated, on the capacitor, without having to apply an additional signal to the terminals, and that based on an evaluation of this voltage, a health state of the circuit may be determined. Hence, a coupling between a control path and a load path, e.g. between a gate-loop and a power-loop, of the circuit may be exploited. The inventors recognized that a priori knowledge about the coupling between those loops or paths may be used in order to categorize the circuit as being healthy, e.g. functioning within predefined tolerances, or unhealthy or respectively faulty, e.g. not functioning within the predefined tolerances. For example, based on an evaluation of electrical quantity induced from a control side of the circuit to a power side of the circuit, a metric for a quality of the circuit may be obtained, e.g. by evaluating a difference of a measured voltage to a threshold.

The voltage across the capacitor, e.g. between the de-energized terminals, may be referred to herein as gate driver-induced residual voltage (GIRV). The inventors recognized that this voltage may appear, e.g. may be measureable, on the de-energized terminals, e.g. DC bus terminals, and may hence be evaluated to differentiate between healthy and damaged circuits, hence for example whether the circuit is a healthy or faulty switching cell. Embodiments may not only allow identifying failures (e.g. of one type) but in particular failures of different kinds, which are for example based on different failure mechanisms (e.g. hence of different types).

To quantify the voltage, the operating modes of the de-energized circuit, may, for example, be analyzed in the time domain. Optionally, the apparatus may be configured to analyze short-circuit, open-circuit, and gate failure conditions, hence being optionally able to detect faulty circuits of all three types.

Embodiments according to the invention may be implemented with low hardware complexity. In particular, apparatuses according to embodiments may be implemented using, for example. only, or for example requiring only, a measurement device, such as a voltage sensor (e.g. a DC bus voltage sensor) and a gate driver (and optionally processing means for an evaluation of the measurement result).

The inventors recognized that the detection of device open- and short-circuit failures, which may, for example, primarily be power-loop effects (e.g. in a load path of the circuit), using a gate-loop excitation (e.g. a driver loop excitation), may or even must rely on a coupling between these two loops.

This kind of coupling between the gate and power loops is present in transistors, such as MOSFETs in the form of the gate-drain junction capacitance. The inventors recognized that this coupling may lead to the above-discussed gate driver-induced residual voltage (GIRV) on the capacitor of the circuit, e.g. as an example a DC bus capacitor of a MOSFET-based switching cell, when the power loop is de-energized. The inventors recognized that in particular based on their GIRV, healthy and damaged switching cells can be differentiated.

According to embodiments of the invention, determining whether or not the circuit is healthy comprises comparing a voltage, e.g. the voltage across the capacitor, to a threshold voltage, and determining, using the comparison, whether or not the circuit is healthy.

In other words, the health of the circuit may, for example, be evaluated by comparing the voltage across the capacitor to a threshold, which may allow obtaining a health information for the circuit with low delay and low computational and hardware complexity. Furthermore, the threshold may be set in order to take into account predetermined test parameters, such as a test robustness, e.g. defining thresholds, so as to aim for a certain robustness regarding false-healthy or false-faulty results, and/or to categorize the circuit in different quality classes.

According to embodiments of the invention, the threshold voltage is determined using one or more properties of the transistors, e.g., a forward voltage of a diode associated with the transistors. For example, when the circuitry is healthy, complementarily driving (720) the plurality of serially connected transistors with the two terminals (10, 11, 410, 411) being in a de-energized state causes an expected voltage (V_{f}) across the two terminals (10, 11, 410, 411), and the threshold voltage (14) may have a value equal to the expected voltage (V_{f}) so as to allow discriminating, by measuring the voltage across the two terminals (10, 11, 410, 411), healthy circuits and faulty circuits.

Thus, in such embodiments the inventive approach allows for distinguishing between healthy/non-faulty and non-healthy/faulty circuits, like switching circuits or modules for modular power converters, like modular multi-level converters, MCMs. When operating such a circuit by only complementary driving the transistors connected in series with the terminals of the circuit being de-energized, a certain or expected voltage is generated due to the charge transfer from the transistors toward the capacitor, and based on this voltage the circuit can be determined to be healthy or faulty by comparing the voltage to a threshold. The threshold may be set according to the specifics of the circuit elements, like the transistors, on the basis of which the expected voltage for a healthy circuit may be determined, and the threshold has a value equal to this expected voltage so that by comparing the measured voltage to the expected voltage a circuit can be determined to be fully functional, i.e., healthy, or non-functional or faulty.

According to embodiments of the invention, the threshold voltage is determined as a fraction of an expected voltage across the capacitor, e.g., ½ or ⅘, of the expected voltage across the capacitor. For example, when the circuitry is healthy, complementarily driving (720) the plurality of serially connected transistors with the two terminals (10, 11, 410, 411) being in a de-energized state causes the expected voltage (V_{f}) across the two terminals (10, 11, 410, 411), and the threshold voltage (14) may a value equal to the fraction of the expected voltage (V_{f}) so as to allow discriminating, by measuring the voltage across the two terminals (10, 11, 410, 411), healthy circuits, which have degraded by less than a certain degree, and non-healthy circuits, which have degraded by the certain degree or by more than the certain degree.

Thus, in addition to the above embodiments allowing for discriminating healthy/fully functional and non-healthy/non-functional or faulty circuits, this embodiment allows for discriminating between circuits which have not yet degraded beyond a certain degree, and circuits which have actually degraded beyond the certain degree. Stated differently, a circuit is considered to be healthy when determining that it has not degraded beyond a certain level, while it is determined to be non-healthy when the circuit degraded beyond the certain level. When operating a healthy system, by complementary driving the transistors with the terminals being de-energized or in an open-circuit state, the charge transfer causes a voltage to be generated across the terminals which is also referred to as the expected voltage for the healthy system. The threshold for determining whether the system is still healthy, i.e., not excessively degraded, or is no longer healthy, degraded beyond a certain level, may be set as a certain fraction of the expected voltage like ⅘ or ½ of the voltage Dependent on this threshold, against which a measured voltage across the terminals is compared, the circuit is deemed degraded or non-degraded. The fraction selected represents a circuit state which, despite the deviation from the expected voltage, is considered to still represent a functional circuit so that this embodiment allows distinguishing not only fully functional and non-functional circuits but also allows for taking into consideration that the circuit may remain functional despite a certain degree of degradation the circuit experiences, for example over its lifetime.

According to embodiments of the invention, the circuit is determined, e.g. classified, not healthy or faulty if a comparison of the voltage, e.g. the voltage across the capacitor, and the threshold voltage yields a comparison signal having a first logical level, e.g., a high level, and/or the circuit is determined healthy if the comparison of the voltage, e.g. the voltage across the capacitor, and the threshold voltage yields the comparison signal having a second logical level, e.g., a low level. This may allow for a simple but efficient evaluation of the measured voltage.

According to embodiments of the invention, the method further comprises logically combining the comparison signal and a gate driver enable signal, which causes the transistors to be driven and which has the first logical level, and the method further comprises, if the comparison signal and the gate driver enable signal have different logical levels, indicating that the circuit is healthy, and if the comparison signal and the gate driver enable signal have the same logical levels, indicating that the circuit is not healthy or faulty.

In other words, the comparison result and gate driver enable signal may be logically combined. Hence, as an example, the method may comprise jointly evaluating an information about the electrical quantity induced in the load path or power loop of the circuit and about a control path or control loop information, e.g. a gate driver enable signal or a delayed version of the gate driver enable signal, in order to obtain the test result for the transistors.

This allows performing the testing with good robustness, since not only the measurement result but also a test status, e.g. a “test has already started” information, e.g. “a test stimulus signal is provided correctly information” can be taken into account.

According to embodiments of the invention, logically combining the comparison signal and the gate driver enable signal comprises applying the comparison signal and the gate driver enable signal to an AND gate. This allows evaluating the test with low hardware complexity and good speed.

According to embodiments of the invention, the method further comprises delaying the gate driver enable signal before logically combining with the output signal of the comparator. This may allow enough build up time to accumulate a sufficient voltage on the capacitor in order to obtain the health information in a robust manner.

According to embodiments of the invention, a delay for delaying the gate driver enable signal is determined using one or more properties of the circuit, e.g., one or more of the following: a switching frequency of the circuit, a capacitance of the capacitor, one or more capacitances of the transistors, like a gate-drain capacitance or a drain-source capacitance, and/or a resistance across the circuit. The inventors recognized that such an approach allows for a simple but efficient test parametrization.

According to embodiments of the invention, driving the plurality of serially connected transistors comprises applying complementary gate driver signals to respective control terminals of the serially connected transistors for complementarily turning on and off the transistors.

As an example, the transistors may be driven with complementary gate signals, e.g. using a complementary pulse signal, the signals having for example a dead time between complementary signal portions. This may allow inducing a gate driver-induced residual voltage, GIRV, in a load path of the circuit and may hence allow obtaining a reliable information on the health of the circuit, e.g. switching cell.

According to embodiments of the invention, driving the plurality of serially connected transistors comprises activating, using the gate driver enable signal, a plurality of gate drivers, which are coupled to the respective transistors.

According to embodiments of the invention, the plurality of serially connected transistors comprises an insulated-gate bipolar transistor, IGBT, and/or a metal-oxide-semiconductor field-effect transistor, MOSFET. Hence, embodiments according to the invention are not limited to a certain type of transistors.

According to embodiments of the invention, the plurality of serially connected transistors comprises two serially connected IGBTs or two serially connected MOSFETs coupled in parallel with the capacitor between the two terminals. The inventors recognized that a serial connection of a same kind of transistors yields a particularly good test reliability.

Embodiments according to the invention comprise an apparatus for testing a circuit, the circuit comprising two terminals, a capacitor coupled between the two terminals and a plurality of serially connected transistors coupled in parallel with the capacitor between the two terminals. Furthermore, the apparatus comprises a driver circuit connectable to the plurality of serially connected transistors for complementarily driving the plurality of serially connected transistors of the circuit, a measurement device for detecting an electrical quantity of the circuit with the two terminals being in a de-energized state and with the plurality of serially connected transistors of the circuit being driven complementarily, and a signal processing circuit coupled to the measurement device for determining, using the electrical quantity, whether or not the circuit is healthy.

According to embodiments, the measurement device is configured to measure a voltage in order to detect the electrical quantity, and the voltage is at least one of a voltage across the terminals, a voltage across the capacitor, a voltage across one or more individual elements in the circuit.

According to embodiments of the invention, the signal processing circuit comprises a comparator for comparing the voltage, e.g. the voltage across the capacitor, to a threshold voltage, outputs (e.g. is configured to output) a first signal indicating the circuit to be not healthy or faulty if the comparator outputs a comparison signal having a first logical level, e.g., a high level, and outputs (e.g. is configured to output) a second signal indicating the circuit to be healthy if the comparator outputs a comparison signal having a second logical level, e.g., a low level.

In other words, the apparatus (e.g. a signal processing circuit thereof) may, for example, comprise a comparator for evaluating the health of the circuit by comparing the voltage across the capacitor to a threshold.

According to embodiments of the invention, the signal processing circuit further comprises a logic gate for logically combining the comparison signal of the comparator and a gate driver enable signal, which causes the transistors to be driven and which has the first logical level.

Furthermore, the logic gate outputs (e.g. is configured to output) the first signal if the comparison signal and the gate driver enable signal have the same logical levels, and the logic gate outputs (e.g. is configured to output) the second signal if the comparison signal and the gate driver enable signal have different logical levels.

In other words, apparatus (e.g. signal processing circuit thereof) may, for example, have a logic gate for combining the comparison result and the gate driver enable signal.

According to embodiments of the invention, the logic gate comprises an AND gate.

According to embodiments of the invention, the signal processing circuit further comprises a delay element for delaying the gate driver enable signal before applying the gate driver enable signal to the logic gate.

According to embodiments of the invention, the driver circuit comprises respective gate drivers connectable to the transistors for applying complementary gate driver signals to respective control terminals of the serially connected transistors for complementarily turning on and off the transistors.

The apparatus as described above is based on the same considerations as the above-described method. The apparatus can, by the way, be completed with all features and functionalities, which are also described with regard to the method and vice versa.

### BRIEF DESCRIPTION OF THE DRAWINGS

Embodiments of the present invention will be detailed subsequently referring to the appended drawings, in which:

FIG. 1 shows an apparatus for testing a circuit, with additional, optional features, according to embodiments of the invention;

FIG. 2 shows a schematic plot of examples of signals for the apparatus shown in FIG. 1 if the circuit is healthy, according to embodiments of the invention;

FIG. 3 shows a schematic plot of signals for the apparatus shown in FIG. 1 if the circuit is faulty, according to embodiments of the invention;

FIGS. 4A to 4C show schematic views of a two-level MOSFET-based switching cell according to embodiments of the invention;

FIG. 5 shows a schematic view of waveforms according to embodiments of the invention;

FIGS. 6A to 6E show schematic views of equivalent circuits of a de-energized cell in a fault condition, according to embodiments of the invention;

FIG. 7 shows a schematic flowchart of a failure detection strategy according to embodiments; and

FIGS. 8A to 8D show schematic views of circuits in different health states together with examples for corresponding signals, according to embodiments of the invention.

### DETAILED DESCRIPTION OF THE INVENTION

Equal or equivalent elements or elements with equal or equivalent functionality are denoted in the following description by equal or equivalent reference numerals even if occurring in different figures.

In the following description, a plurality of details is set forth to provide a more throughout explanation of embodiments of the present invention. However, it will be apparent to those skilled in the art that embodiments of the present invention may be practiced without these specific details. In other instances, well-known structures and devices are shown in block diagram form rather than in detail in order to avoid obscuring embodiments of the present invention. In addition, features of the different embodiments described herein after may be combined with each other, unless specifically noted otherwise.

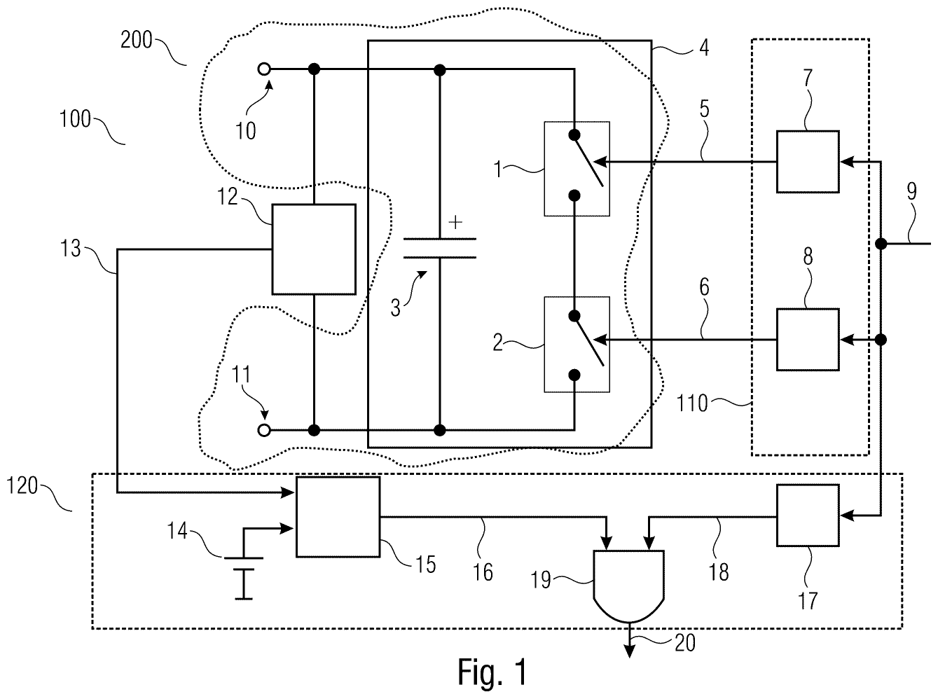

FIG. 1 shows a schematic view of an apparatus for testing a circuit, with additional, optional features, according to embodiments of the invention. FIG. 1 shows apparatus 100 for testing a circuit 200, the circuit comprising two terminals 10, 11, a capacitor 3 coupled between the two terminals 10, 11 and a plurality of serially connected transistors 1, 2, coupled in parallel with the capacitor 3, between the two terminals 10, 11. The apparatus 100 comprises a driver circuit 110 connectable to the plurality of serially connected transistors 1, 2 for complementarily driving the plurality of serially connected transistors of the circuit 200.

The apparatus 100 comprises a measurement device 12 for detecting an electrical quantity of the circuit with the two terminals 10, 11 being in a de-energized state and with the plurality of serially connected transistors 1,2 of the circuit being driven complementarily.

Furthermore, the apparatus 100 comprises a signal processing circuit 120 coupled to the measurement device 12 for determining, using the electrical quantity 13, e.g. a voltage across the capacitor 3, whether or not the circuit 200 is healthy.

In the example of FIG. 1, a measurement of the electrical quantity in the form of a voltage across the terminals 10, 11, representing a voltage across the capacitor 3, is shown. However, embodiments are not limited to such approaches. Optionally, a voltage across one or more individual elements in the circuit can be measured and evaluated. As an example, any electrical quantity (e.g. a voltage and/or a current) in a load path or power loop of the circuit (e.g. across the capacitor 3, e.g. across an additional resistor, e.g. across a transistor 1, 2) that is induced by the complementarily driving of the plurality of serially connected transistors 1, 2 may be measured and analyzed. Such measurements may comprise voltage measurements, as well as current measurements, or other measurements related to an electrical quantity suitable for the respective application.

In this regard, it is to be noted that a plurality of optional, additional features are shown in FIG. 1, as will be explained in the following. In particular, the specific details of the signal processing circuit 120, e.g. having a fixed threshold voltage 14, a comparison block, 15 and a time delay block 17 are optional. In other words, measured signal 13 may be any measurement signal about an electric quantity of the circuit 200, which is influenced by a coupling between a control loop and a power loop of the circuit, and may hence be evaluated in any manner that allows analyzing this measured signal to determine whether the coupling corresponds to a healthy circuit or not.

Nevertheless, for a thorough understanding of embodiments, FIG. 1 is discussed in the following, according to a first example with a plurality of optional features.

As an example, the transistors 1, 2, may, for example, be insulated-gate semiconductor devices, which may be arranged, together with capacitor, 3 to form a switching cell, 4, for example, as a structural and functional unit of a power converter.

The gate drive signals, 5 and 6, to the semiconductor devices, 1 and 2, may be used to turn the devices on and off. The gate drive signals, 5 and 6, may be generated by the respective gate drivers, 7 and 8. The driver circuit 110 may hence comprise the gate drivers 7 and 8. The gate drivers, 7 and 8, may be activated by an enable signal, 9.

It is to be noted that herein, transistors may be referred to as “device”.

According to inventive methods, the terminals 10, 11 (e.g. DC terminals of the switching cell 4) may be de-energized and the voltage measurement device, 12, may be connected across the terminals 10, 11. The voltage, 13, across the capacitor, 3, may hence be measured by the measuring device, 12.

The measured voltage, 13, may be fed, optionally along with a fixed threshold voltage, 14, to a comparison block, 15. The output, 16, of the comparison block, 15, may be at a high level if the measured voltage, 13, is higher than the threshold, 14; otherwise, the output of the comparison block may be at a low level. However, it is to be noted that embodiments are not limited to this kind of comparison, apart from thresholds, gradients or statistical analysis of signal developments may be performed.

The gate driver enable signal 9 may optionally be passed through a time delay block, 17, to obtain the delayed gate driver enable signal, 18. The comparison output, 16, may be ANDed with the delayed gate driver enable signal, 18, using the AND block, 19. If the fault indicator output, 20, of the AND block is at a high level, a failure of one or both of the devices of the switching cell, 4 may be indicated; otherwise, if the AND block output, 18, is at a low level, it may be indicated that the switching cell, 4, is healthy. Again, other health-indications are possible as well. In particular the processing may be performed using analog or digital processing means.

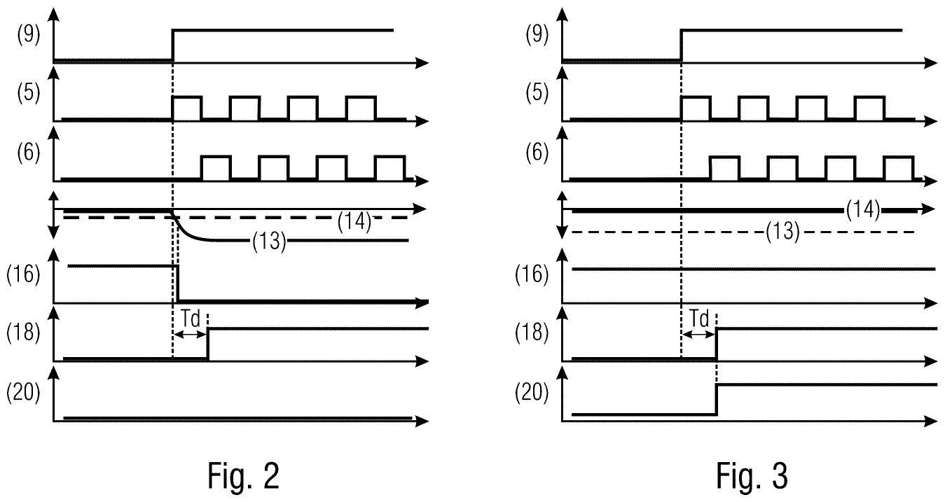

Next, reference is made to FIGS. 2 and 3, showing schematic views of examples of signals for the apparatus shown in FIG. 1, according to embodiments of the invention.

As shown in FIGS. 2 and 3, the enable signal, 9, may be set to a high level. The gate drive signals, 5 and 6, to the devices, 1 and 2, may hence be activated. The threshold, 14, may have a constant value, e.g. of negative 0.2 volts.

As shown in FIG. 2, if the cell is healthy, a negative value of the voltage, 13, lower than negative 0.2 volts, may be measured after the gate driver enable signal, 9, is activated. It is to be noted again (as in the previous paragraph) that the negative 0.2 volts here is an example value. Other values are also naturally possible. Hence, the threshold comparison output, 16, may become low. The delay, Td, in the delayed enable signal, 18, may be adjusted or may be set, such that the delayed signal, 18, becomes high only after the comparison output, 16, becomes low. Consequently, the fault indicator output, 20, may remain low, indicating a healthy switching cell.

As shown in FIG. 3, if the cell is damaged, a non-negative value of the voltage, 13, e.g. higher than negative 0.2 volts, may be measured after the gate driver enable signal, 9, is activated. Hence, the threshold comparison output, 16, may remain high. When the delayed gate driver enable signal 18, becomes high, the fault indicator output, 20, may also become high, indicating a failure within the switching cell.

### Advantages of Embodiments

For a better understanding of the advantages of methods and apparatuses according to embodiments, reference is made to conventional approaches.

According to a first group of conventional approaches, semiconductor device failures are detected by measuring the on-state and off-state gate currents of an insulated gate type power semiconductor device. A device is classified as being damaged if its on-state gate current is higher than the on-state gate current of a healthy device, or if its off-state gate current is lower than the off-state gate current of a healthy device. In comparison to such approaches, embodiments according to the invention have the following advantages:

Methods according to embodiments do not require the sensing of gate currents of the semiconductor devices, and are hence non-invasive. Gate current sensors are not a part of the normal operation of power converters and hence it is not desirable to include the same “just” or primarily for testing. Accordingly, embodiments allow reducing a hardware complexity for the testing.

Methods according to embodiments can be used to detect gate failures of the semiconductor device and open-circuit failures, i.e., disconnection failures, and short circuit failures of the semiconductor device, which is not possible based on approaches of the first group since they allow detecting only gate failures.

Methods according to embodiments do not require a knowledge of the on-gate and off-gate currents of a healthy device. Hence, according to embodiments no additional exercises or pre-tests to determine the on-state and off-state gate currents of the healthy device are required, reducing testing effort.

According to a second group of conventional approaches, a gate-failure of insulated gate semiconductor devices is detected through a mismatch in the actual gate voltage and the gate voltage command. In comparison to such approaches, embodiments according to the invention have the following advantages:

Methods according to embodiments do not require the sensing and rectification of gate currents of the semiconductor devices, and are hence non-invasive. Gate current sensors are not a part of the normal operation of power converters and hence it is not desirable to include the same “just” or primarily for testing. Accordingly, embodiments allow reducing a hardware complexity for the testing.

Methods according to embodiments can be used to detect short-circuit and open-circuit failures of the semiconductor device, in comparison to the second group of conventional approaches, which are useful only to detect gate failures of the semiconductor devices.

According to a third group of conventional approaches, an excessive voltage across the semiconductor device in the on state is used as an indicator of device failure or a power loop fault. In comparison to such approaches, embodiments according to the invention have the following advantages:

Methods according to embodiments do not require additional components in the gate drive circuit of the semiconductor device, and are hence non-invasive.

Methods according to embodiments can be used to detect short-circuit failures and gate failures of the semiconductor device in de-energized power converters, wherein approaches according to the third group can only be used to detect open-circuit faults of semiconductor devices.

The technical characteristics described above, and in particular in the context of FIGS. 1 to 3 may have one or more of the following effects and advantages:

Embodiments according to the invention allow detecting and locating at least three major modes of failure-open-circuit failure, short-circuit failure, and gate failure—of transistors such as insulated-gate semiconductor devices prior to energization of the circuit, e.g. in the form of a power converter, unlike conventional approaches according to the first, second and/or third group, none of which are useful to detect all three failure modes. This may be one of or may even be the most important advantage of embodiments according to the invention.

The process, e.g. a testing method according to embodiments, may be performed non-invasive, since it does not require access to any additional signals within the circuit, e.g. power converter. The measured voltage used for detection may be available from existing voltage sensors, such as voltage sensors connected to a power converter, for example implemented for a regular operation of the power converter, and hence not implemented as additional test specific hardware. Even if such a sensor is not present, according to embodiments, the same can be connected to the circuit, e.g. to the converter terminals and does not require access to the inner circuit of the power converter. Thus, embodiments according to the invention may be cheap and straightforward to implement. In contrast, conventional technology according to the first, second and/or third group require access to and invasion of the semiconductor device gate drive circuit.

Embodiments according to the invention may utilize few, or even minimal components. As an example, embodiments according to the invention may, for example, utilize a voltage threshold generation, an AND gate, a time-delay block, and a comparator. Embodiment do not require extensive prior measurements (e.g. as required by conventional approaches according to the first group).

In particular, embodiments according to the invention allow the detection of device failures in de-energized power converter systems and hence reduce the risk of multiple, successive faults after energization.

Again, it is to be noted, that embodiments are not limited to a measurement of the capacitor voltage. Another possibility is to use other physical quantities, rather than the measured voltage (e.g. 13 in FIG. 1) across the terminals (e.g. switching cell terminals), to draw the same conclusions regarding the health of the circuit (e.g. switching cell). The voltage across individual devices in the switching cell could be a possible quantity.

As an example, a method according to embodiments may comprise driving two serially coupled insulated gate transistors with complementary gate signals, e.g. a complementary pulse signal, e.g. having a dead time between complementary signal portions, in order to induce a signal (e.g. a voltage signal, e.g. v_{f}, e.g. a current signal, e.g. a gate driver-induced residual voltage, e.g. GIRV, in a load path, e.g. power loop) of the switching cell, while the first and second terminal are in a de-energized state (e.g. not provided with a voltage, e.g. not provided with a test signal, e.g. not provided with a load path test signal). In addition, the method may comprise obtaining and evaluating an information, e.g. an accumulated voltage on the conductor, about the signal induced from a control or gate path to the load path of the switching cell, in order to obtain a test result for the insulated-gate transistors.

Obtaining and evaluating the information may comprise measuring at least one of a voltage over a load path of at least one of the insulated-gate transistors, a voltage between the first and second terminal, a voltage, e.g. V_{f}, of the capacitor, a charging state of the capacitor, and/or a current induced in the load path of the switching cell.

Furthermore, it is to be noted again that methods according to embodiments, may comprise jointly evaluating the information about the signal induced in the load path of the switching cell and a control path information, e.g. a gate driver enable signal or a delayed version of the gate driver enable signal, of the switching cell, in order to obtain the test result for the insulated-gate transistors.

Optionally, processing means of an apparatus according to embodiments may be configured to evaluate the information about the signal induced in the load path of the switching cell, in order to falsify that the insulated-gate transistors are subject to any of an open-circuit failure, a short-circuit failure and a gate failure.

At least some apparatuses or devices according to embodiments may comprise or even rely (a) on the enabling of the gate drivers, but not the power-loop circuits of the transistors (e.g. insulated-gate semiconductor device), and (b) may use the measured voltage, (e.g. 13 in FIG. 1) across the circuit or switching cell, to distinguish healthy and damaged devices, for example in a power converter.

Hence, embodiments may comprise a failure detection strategy, which both (a) functions, for example only, under the activation of gate-drive signals, and (b) distinguishes damaged devices from healthy ones if the switching cell terminals (e.g. 10 and 11 in FIG. 1) are kept disconnected, but fails to distinguish damaged devices from healthy ones when the terminals (10 and 11) are connected to an external voltage source of polarity such that the terminal labelled 10 is at higher electric potential.

In general, embodiments according to the invention may be suitable for application to all power converter systems which have a large number of modular switching cells, wherein the detection, location, and isolation of faulty switching cells prior to energization is beneficial or even necessary to prevent cascading failures in the system. Examples include: a. Modular high-voltage DC-AC power converters for medium-voltage drives and high voltage direct-current transmission, b. Solid-state transformers and DC energy hubs for smart distribution systems, c. Two-level voltage-source inverter applications, e.g. In grid-connected and solar micro-inverter applications.

In the following, embodiments are further discussed. In particular, principles of embodiments regarding driver-induced residual DC link voltage-based detection of switching cell failure are further highlighted.

As discussed above, embodiments allow detecting faulty switching cells, prior to power-loop energization, for example, using no additional (e.g. only or primarily test specific) hardware. The inventors recognized that utilizing a gate driver-induced residual voltage (GIRV), appearing on the de-energized DC bus, allows differentiating between healthy and damaged cells and hence, allows identifying failures. The GIRV may be quantified by analyzing the operating modes of the de-energized switching cell (e.g. in time domain). Embodiments, discussed in the following may be implemented with low hardware complexity, for example comprising only a measurement device, driver circuit and signal processing circuit.

In the following, as an example, a detection of device failure (e.g. transistor failure) in a generic two-level switching cell, which may be an ubiquitous building block of power converters, is discussed. However, embodiments are not limited to an application to such circuits. Furthermore, in particular power MOSFETs are considered in the following due to their wide scope of application, especially with the advent of wide-bandgap devices. Yet again, it is to be noted that embodiments may be implemented based on a variety of transistor designs and are not limited to MOSFETs.

First, an overview of an approach according to embodiments is given:

(i) The gate driver-induced residual voltage (GIRV) appearing across the DC link of a de-energized MOSFET-based 2-level switching cell, due to the coupling between the gate and power loops, may be exploited.

(ii) The GIRV may be quantified based on a time-domain analysis of the operation of the de-energized switching cell, considering the device parasitics. Embodiments may further exploit dependencies of the GIRV on various device, circuit, and modulation parameters, based on which, for example, evaluation of the electrical quantity may be performed or adapted, e.g. for setting voltage thresholds for comparison.

(iii) Evaluation of the electrical quantity may be performed based on the finding that the GIRV may change under short-circuit, open circuit, and/or gate failure of the device.

(iv) Hence, embodiments may comprise a strategy to identify and locate failures of switching cells, utilizing the difference in the GIRV of healthy and damaged switching cells. Accordingly, embodiments may provide an apparatus for an implementation of the proposed strategy, as an example, using only the DC bus voltage sensor of the switching cell.

(v) The analysis of the GIRV was verified in both circuit simulations and experiments.

(vi) The proposed failure detection strategy according to embodiments was also validated in simulation and on existing converter hardware, using no additional components.

In general, the analysis of the electrical entity may be performed using manufacturer provided parameters of the circuit and in particular of the device and also the driver circuit and modulation parameters, which may have influence on the GIRV.

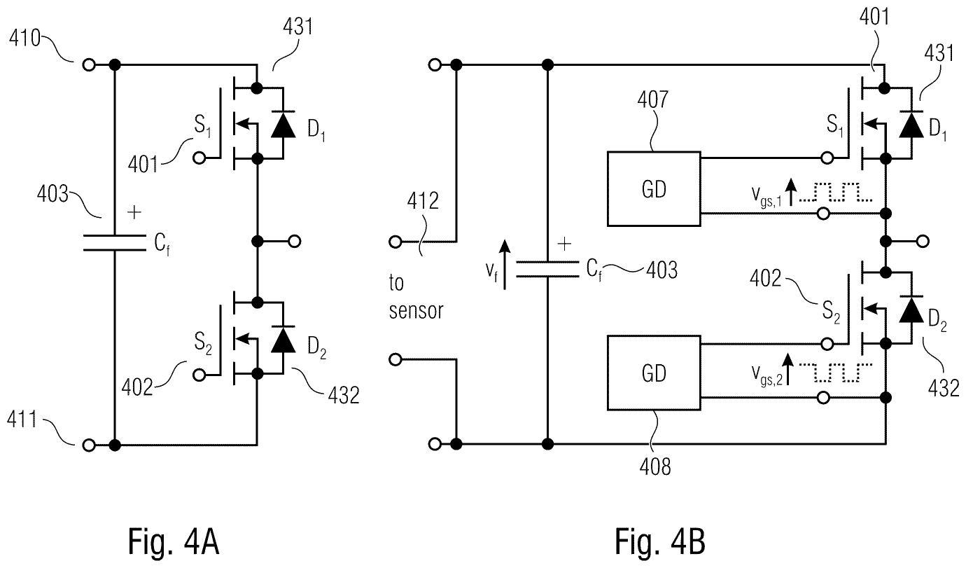

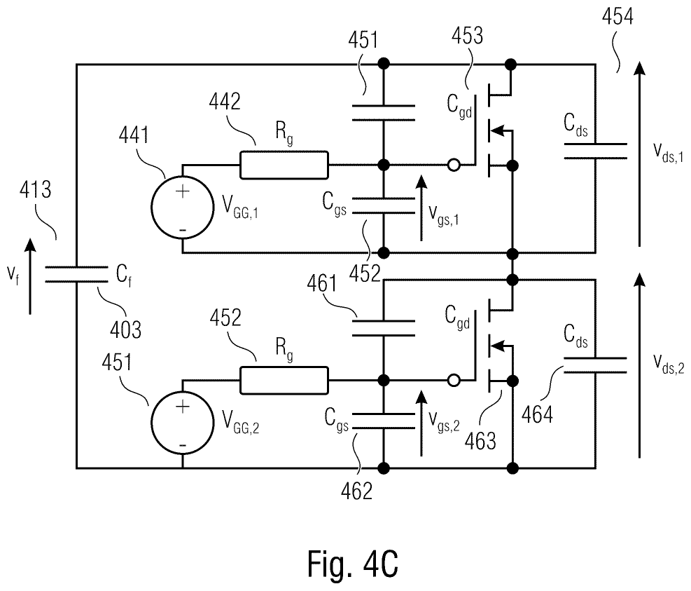

In the following, reference is made to FIG. 4, showing schematic views of a two-level MOSFET-based switching cell according to embodiments. FIG. 4 shows: (a) Schematic of canonical two level switching cell, with (b) the gate driver and the coupling between DC bus voltage and gate driver excitation. (c) Detailed equivalent circuit of the switching cell showing the gate driver and the junction capacitances.

A two-level MOSFET-based switching cell, denoted simply as a cell, is shown in FIG. 4a. The cell comprises two MOSFETs 401, 402 (S₁ and S₂), body and/or external antiparallel diodes 431, 432 (D₁ and D₂), and the DC link capacitor 403, C_{f}. The isolated gate driver 407, 408 (GD) for each MOSFET is represented as a generic block in FIG. 4b. The activation of the drive signals to the MOSFETs produces a voltage, v_{f}, on the DC link capacitor 403 as indicated in FIG. 4b. The detailed equivalent circuit of the cell is shown in FIG. 4c. Quantities corresponding to the top and bottom devices are represented using the subscripts, 1 and 2, respectively. Each gate driver 407, 408 is represented as a voltage source 441, 451, V_{GG}, in series with a gate resistor 442, 452, R_{g}. The gate circuit parameters as well as the gate-source 452, 462 (C_{gs}), drain-source 454, 464 (C_{ds}), and gate-drain 453, 463 (C_{gd}) capacitances may, for example, be assumed to be identical for both devices.

It is to be noted that accordingly named elements of FIG. 4 may optionally correspond to respective elements of FIG. 1 and vice versa, e.g. element 4xx corresponding to element xx. Hence, in FIG. 4, an example for terminals of the cell are accordingly indicated by elements 410 and 411. Hence, corresponding features may have similar or identical features functionalities and details as their counterpart. Signal 412 may be provided to a respective measurement device 12, hence for example a voltage measurement device.

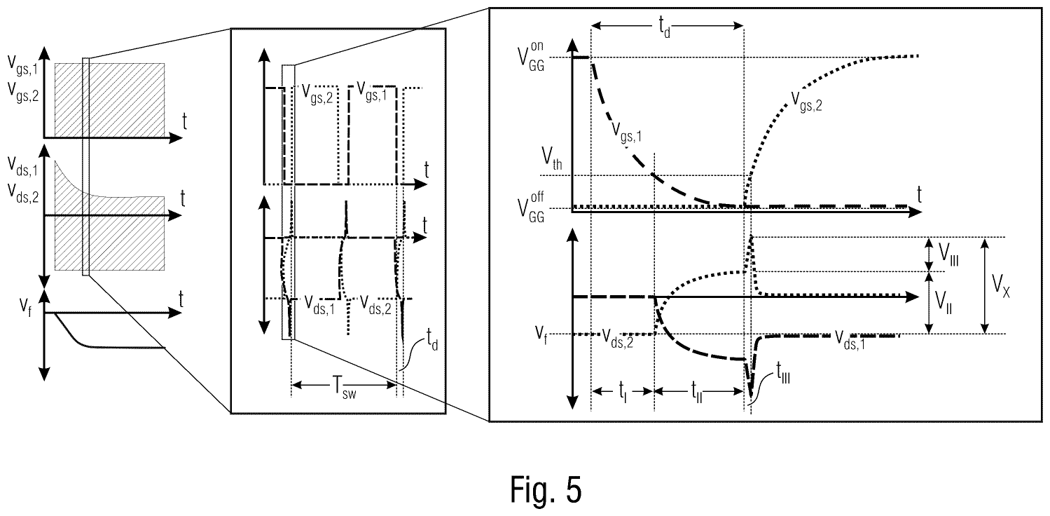

The cell may be operated with the power loop de-energized. The gate pulses to the devices are complementary, optionally with a dead time, t_{d}. The gate-source voltage waveforms, magnified to the time scale of the switching transition, are shown in FIG. 5.

FIG. 5 shows a schematic view of waveforms according to embodiments of the invention. FIG. 5 shows representative waveforms of gate-source (v_{gs}), drain-source (v_{ds}), and DC bus (v_{f}) voltage at both initial and steady-state conditions (e.g. as indicated in FIG. 4). The presence of the gate-drain capacitances may couple these gate loop voltages to the power loop, producing non-zero drain source voltages, also shown in FIG. 5. The drain-source voltage may be responsible for charging the DC link capacitor, C_{f}, up to a voltage, V_{f}.

In the following, optional details regarding a time-domain analysis and quantification of the GIRV according to embodiments are further highlighted:

The switching transition, shown in FIG. 5, may begin with the turn-off command to one device of the cell and may end with the turn-on of the other device. Based on this transition the voltage, V_{f} can be quantified. Broadly, the transition may involve the charging of the device drain-source capacitances, and their subsequent discharging into the DC bus capacitor, C_{f}. The circuit operation may proceed in four stages.

(i) Stage I (0≤t<t_{I}): This stage may begin with the OFF command to the top switch (S₁), whose gate voltage, v_{gs,1}, falls, as shown in FIG. 5. This stage may continue while S₁ is turned ON and ends when v_{gs,1} falls below Vₜₕ.

During this stage, the voltage, v_{ds,1}, is clamped by the ON resistance of the top switch. Hence, the power-loop quantities, v_{ds,1} and v_{ds,2}, may not vary appreciably, e.g. significantly. The impact of this stage in the context of gate and power loop coupling may, for example, be negligible. However, the duration, t_{I}, of this stage may impact the durations of the remaining stages.

(ii) Stage II (0≤t−t_{I}<t_{II}): The turn-off of S₁ may initiate this stage. The voltage, v_{ds,1}, may, for example be not clamped, since S₁ is turned off. Thus, the continued may fall of the gate-source voltage, v_{gs,1}, may be reflected in the power-loop quantities, v_{ds,1} and v_{ds,2}. The drain-source capacitances may be charged due to the coupling with the gate loop of S₁. Stage II may end with the dead time (t_{d}), and hence the duration of stage II may be given by t_{II}=tₐ−t_{I}.

The gate-source voltage, v_{gs,1}, at the end of stage II is denoted by Vᵢ. The change in the drain-source voltages (v_{ds,1} and v_{ds,2}) during stage II may, for example, not depend on the value of the voltage, v_{f}, but rather on the MOSFET parameters, gate driver parameters, and the duration, t_{II}. The drain-source voltage increment in stage II, V_{II}, is marked in FIG. 5 and may quantify the charging of the drain-source capacitances in this stage.

(iii) Stage III (t_{I}+t_{II}≤t<t_{I}+t_{II}+t_{III}): During this stage, S₂ is commanded ON. The gate-source voltage of S₂ may rise in response to the turn-on command. This change in v_{gs,2} may lead to corresponding changes in v_{ds,1} and v_{ds,2}, for example, since neither switch is conducting and the gate and power loops are coupled. The voltage increments may have the same polarity as the respective increments in stage II.

Similar to stage II, the drain-source voltage increment in stage III, V_{III}, may be independent of v_{f} as it is marked on FIG. 5. The v_{ds,1} and v_{ds,2} increments in stages II and III may, be cumulative.

(iv) Stage IV (t_{I}+t_{II}+t_{III}≤t<T_{sw}/2): In this stage, the energy stored in the drain-source capacitances during stages II and III may be discharged into the de bus capacitor.

The quantity, V_{III}, represents the voltage across the drain source capacitance of the turned-off device prior to its turn on. This voltage may depend on the initial voltage across the device, and also on the voltage increments calculated using the relations derived for stages II and III. The total voltage increment at the end of stage III is denoted by V_{X}, which may be independent of the initial voltage across the drain-source capacitance.

According to some embodiments, providing a gate signal in order to achieve stage II, II, IV may, for example, be required, so that, optionally only II and IV, or only III and IV may be insufficient.

In the following, loading effects of body diodes and resistive circuits according to embodiments are discussed.

Resistors are commonly connected to a DC bus, especially as bleeders to balance split capacitors or to couple the DC bus to voltage sensing circuits. These resistors can be lumped together as a single resistance, R_{dc}, connected across the DC bus. A change of the voltage across C_{f} for example twice every switching cycle, may be considered for evaluation a charge balance equation, which may be considered for the evaluation of the circuit.

Body diodes are intrinsic to Si- and SiC-based MOSFETs. The polarity of the coupling voltage forward biases the body diodes, leading to a loading effect that is quantified by the Shockley relation This effect may as well be considered in order to determine the stead-state voltage V_{f}, considering loading effects, in order to determine the health information.

In the following a parameter dependence of the GIRV, which may be exploited for the determination of the health information according to embodiments is discussed.

The GIRV (V_{f}) may depend on the parameters of the MOSFET, the gate drive circuit, and the modulation scheme. The influence of each of these parameters on the GIRV may analyzed for different switching cells and a test parametrization, e.g. threshold determination may be performed based on a priori knowledge of such influences, e.g. in switching cell type-specific or even switching-cell-specific (e.g. individual) manner.

Of the device capacitances, the gate-drain capacitance, C_{gd}, may, for example, constitute the coupling branch between the gate driver and the power loop. Hence, the variation of C_{gd} may have a drastic effect on the GIRV. The influence of the gate source (C_{gs}) and drain-source (C_{ds}) capacitances may be much lower in comparison.

Since the circuit time constants in stages I, II, and III may be proportional to the gate resistance, R_{g}, higher R_{g} values may slow down these transitions and hence, may reduce the magnitude of charge transfer. Hence, high R_{g} values may reduce the GIRV.

The GIRV may, for example, be influenced primarily by the charging of the drain-source capacitances in stages II and III. Both these intervals may involve a gate-source voltage change between V^{off}_{GG} and Vₜₕ. Hence, the difference between the gate ON voltage and the threshold voltage (V^{on}_{GG}−Vₜₕ) may have a negligible influence on the GIRV. In contrast, the difference between the gate OFF voltage and the threshold voltage (V^{off}_{GG}−Vₜₕ) may affect the GIRV significantly.

As the threshold voltage varies between units of a particular MOSFET product, the quantification of the variation in the GIRV may be relevant to its use for fault detection and may hence be considered for the evaluation of the electric quantity. The GIRV may exhibit a strong dependence on the switching frequency, f_{sw}. Since the GIRV may develop due to a fixed charge transfer on every switching transition, it may increase with the frequency of these transitions, i.e., the switching frequency. The rate of increase may level off at higher values of the GIRV, e.g. due to the nonlinear loading effect of the diodes. Finally, low values of the dead time (t_{d}) may allow insufficient time for stage II and hence reduce the GIRV.

In the following, failure detection methodologies according to embodiments are discussed:

The charge transfer mechanism from the gate driver to C_{f} in a healthy cell, discussed above, may produce a voltage, V_{f}, across the DC bus. The mechanism may depend on three distinct processes, namely, the accumulation of charge on the drain source capacitance of the turned-off device, the transfer of this charge to C_{f}, and the retention of the charge on C_{f}.

In a faulty cell, the interruption of one or more of these processes may significantly affect the voltage, V_{f}. This may allow the discrimination of faulty and healthy cells by measuring the voltage, V_{f}; the way in which V_{f} is affected may depend on the type of fault in the cell. Each fault may be considered to occur on the top switch (S₁) in the subsequent analysis.

### A. Short-Circuit Faults

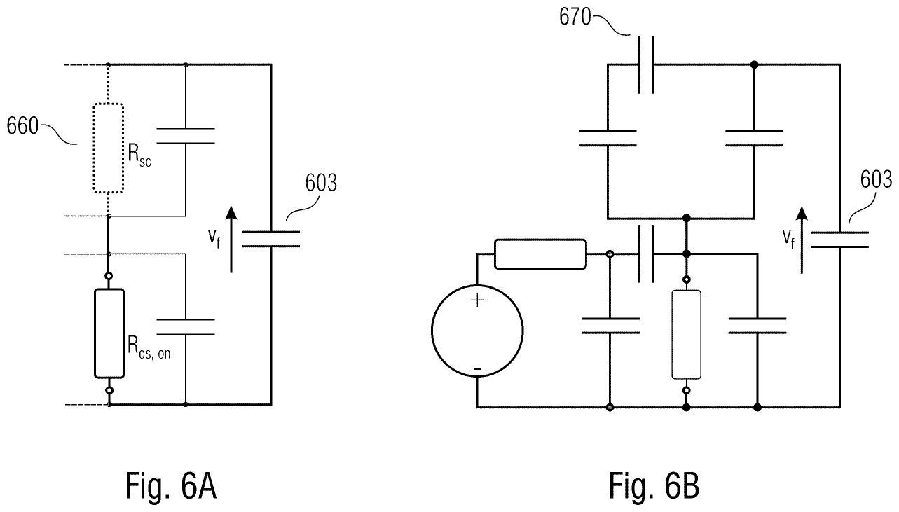

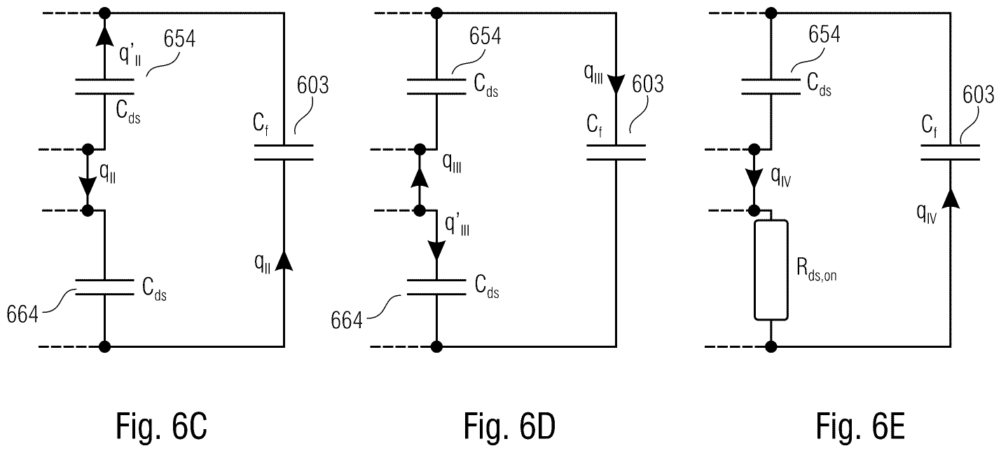

Reference is made to FIG. 6. FIG. 6 shows schematic views of equivalent circuits of a de-energized cell in a fault condition according to embodiments: (a) Short-circuit fault causing the discharge of the GIRV in stage IV. (b) Open circuit or gate fault, with the faulty top device replaced by its equivalent capacitance network. Transfer of charge to C_{f} shown using simplified charge flow circuits for stages (c) II, (d) III, and (e) IV. The elimination of stage II in an open-circuit or gate fault may cause the charges transferred in stages III and IV to cancel out.

The faulty device may be modeled as a resistor, R_{sc} 660, between the drain and source terminals, as shown in FIG. 6. When the healthy device is turned on in stage IV, any voltage on C_{f} (e.g. capacitor 603, e.g. corresponding to capacitor 3 of FIG. 1 or 403 of FIG. 4) may be discharged into a short circuit. Thus, a cell with one or both devices short-circuited may exhibit negligible voltage across C_{f}. Since even large resistors (such as bleeders) impose a loading effect on the GIRV, short-circuit resistances of magnitude several orders higher than the device on-resistance may eliminate the GIRV. Thus, methods according to embodiments allow detecting short-circuit failures, even those with appreciable (e.g. significant) short-circuit resistance.

### B. Open-Circuit and Gate Faults

The device may fail to turn on in case of an open-circuit failure or a failure of the device gate or the gate driver. In this case, the device may represented only as a network of equivalent capacitors 670, and these capacitances might differ from that of a healthy device. The charge flow during operation of a healthy de-energized cell is shown, for stages II, III, and IV, in FIGS. 5c, 5d, and 5e, respectively. The charges transferred to C_{f} during stages II and III, denoted as q_{II} and q_{III}, respectively, are in opposite directions and nearly equal magnitude. Hence, these may cancel out, and the GIRV may develop due to the charge (q_{IV}) transferred to C_{f} in stage IV. If S₁ is open-circuited, stage II may be eliminated from operation. The total charge transferred to C_{f} is (q_{III}-q_{IV}), which can be shown to cancel out in this case. Hence, no GIRV may develop.

### C. Failure Detection Strategy and Implementation

The absence of voltage across the de-energized DC bus may indicate a fault in the switching cells connected to that DC bus. In general, the detection of this fault is implementable according to embodiments without including new components in the power converter, and a strategy for the same is described as follows.

The gate drive signals of a switching cell may be activated first. In case of multiple switching cells connected to a DC bus, for instance in a H-bridge configuration, only the gate signals of the cell under test are activated. During the test, source and load breakers may be disconnected to keep the DC bus isolated. The coupling voltage measured by the voltage sensor at the DC bus may then be measured. The sensed voltage prior to and post gate signal activation may be compared to eliminate sensor offset. The difference between the two is compared with a threshold calculated using the simple method explained above. If the difference is lower than the threshold, a fault alarm may be raised for the phase leg under test.

In the following some embodiments are summed up:

According to embodiments, a strategy to detect failures in transistor circuits, such as MOSFET switching cells, is performed based on a mode of capacitive coupling between the gate and power loops, e.g. between a control path and a load path. The coupling mode may be analyzed and the coupling voltage, which may be used to distinguish between healthy and faulty cells, is quantified, e.g. in the form of a threshold for comparison.

An implementation according to embodiments may comprise standard voltage sensors, analog-to-digital converters, and digital control platforms. Embodiments may allow achieving an error comparable to deviations arising due to differences between identical devices. The proposed fault detection method according to embodiments was validated on hardware using existing gate drivers and DC bus voltage sensors and may hence be implemented into existing hardware setups without or with limited changes to the architecture. The proposed strategy according to embodiments is valuable for detecting faulty circuits, such as MOSFET switching cells in de-energized power converters, for example, using only the gate drive excitation and the existing DC bus voltage sensor (e.g., a simple resistive divider).

Consequently, the strategy according to embodiments can be implemented by incorporating the testing routine into the power converter start-up protocol, for example, without necessitating changes to the existing hardware. Furthermore, the parameters required for fault detection can be estimated using only known circuit and modulation parameters, optionally along with manufacturer provided MOSFET data; no additional device characterization is necessary. Thus, methods according to embodiments are both simple and widely applicable for detecting faults in power converters before start-up.

In the following, reference is made to inventive details regarding the selection of threshold voltages, e.g. for selecting the threshold voltage, 14, in FIG. 1.

The semiconductor devices, 1 and 2, in FIG. 1 may, for example, be either MOSFETs or IGBTs. MOSFETs have an internal body diode whose forward voltage, V_{D}, can be found from the datasheet of the MOSFET. IGBTs usually have an external antiparallel diode connected across them; again, the forward voltage, V_{D}, of this diode can be found from its datasheet.

The threshold voltage, 14, is recommended (e.g. may be set) as −V_{D}/10 (e.g. with a tolerance of +/−10%). Since power semiconductor diodes have a forward voltage, V_{f}, in the range of 1.5 to 2.0 volts, this means that a fixed value of negative 0.2 volts can, for example, be used for the threshold voltage, 14. Hence, such a setting may allow providing a good default test parametrization.

An alternative method to the above may comprise calculating the expected voltage, V_{f}, across the capacitor 3, in FIG. 1, then, the threshold voltage, 14, in FIG. 1 can be set based on V_{f}, e.g. as V_{f}/2 (e.g. with a tolerance of +/−10%).

Hence, the threshold voltage according to embodiments may, in general, be determined using one or more properties of the transistors, e.g., a forward voltage of a diode associated with the transistors, or-as a fraction of an expected voltage across the capacitor, e.g., ½ of the expected voltage across the capacitor.

In the following, reference is made to inventive details regarding the selection of the time delay, T_{d}, e.g. as indicated in FIGS. 2 and 3: The time delay T_{d} may be calculated based on a time constant t. The time constant, t may be determined according to

$$τ = \frac{{C}_{f}}{2 {f}_{sw} ( {C}_{gd} + {C}_{ds} ) + \frac{1}{{R}_{dc}}}$$

wherein
f_{sw}=switching frequency
C_{f}=Capacitance of the switching cell capacitor, 3
C_{gd}=Semiconductor device gate-drain capacitance
C_{ds}=Semiconductor device drain-source capacitance
R_{dc}=Resistance connected across switching cell

Then, the time delay, T_{d}, may be calculated with an error margin of 10×, i.e., T_{d}=10τ.

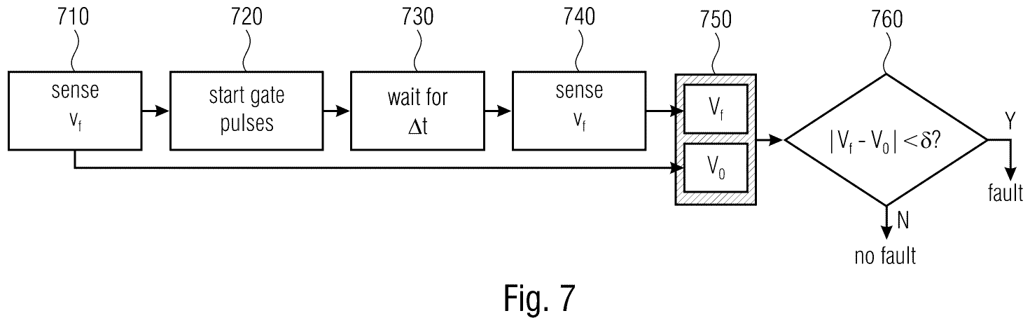

Furthermore, reference is made to FIG. 7. FIG. 7 shows a schematic flowchart of a failure detection strategy according to embodiments. Hence, as an optional feature, an electrical quantity, e.g. V_{f}, may be measured or sensed, 710. Based thereon, V₀, which is the value of the voltage across the capacitor before the test starts may be determined and, for example, stored, see 750, e.g. as a reference value. Furthermore, the plurality of serially connected transistors may be driven complementarily (e.g. after determining V₀), e.g. activated by a start gate pulse, with the two terminals of the circuit being in a de-energized state, 720. Optionally, the gate driver enable signal may be delayed, 740, before evaluation, e.g. before being logically combined with the output signal of the comparator. Furthermore, based on a sensing or measuring of the electrical quantity, e.g. V_{f}, during provision of the gate driver signals, 740, a voltage V_{f} across the terminals (which is hence measured after the test starts) may be determined. The difference between the voltage of the capacitor before the test started, V₀, and the voltage of the capacitor measured during the test, V_{f}, namely (V_{f}−V₀), may be the accumulated voltage due to the driver. The difference or optionally an absolute difference, e.g. |V_{f}−V₀|, may be compared to a threshold δ, 760 in order to obtain the health information, e.g. “Fault” or “No fault”.

Hence, embodiments may comprise considering and optionally determining a reference value, e.g. V₀, in order to determine an accumulated electrical quantity in a load path of the circuit, caused by a test stimulus provided to a control path of the circuit.

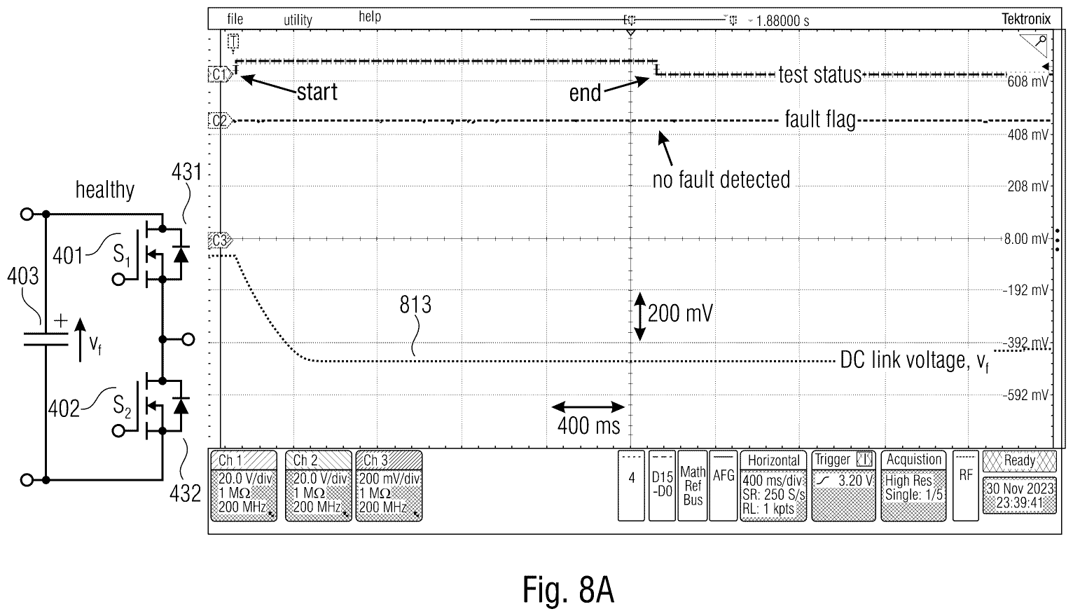

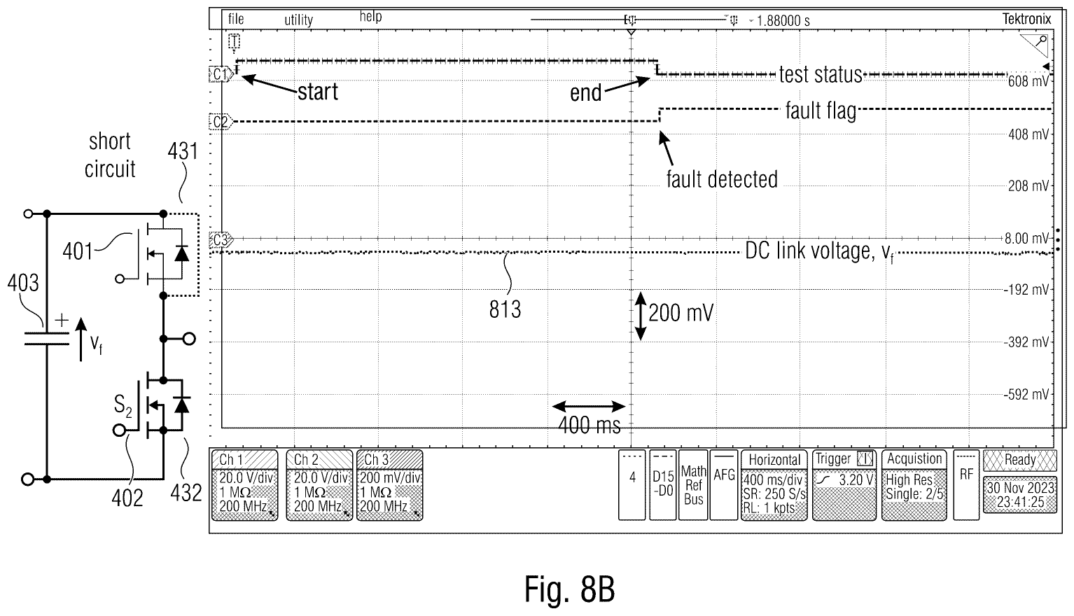

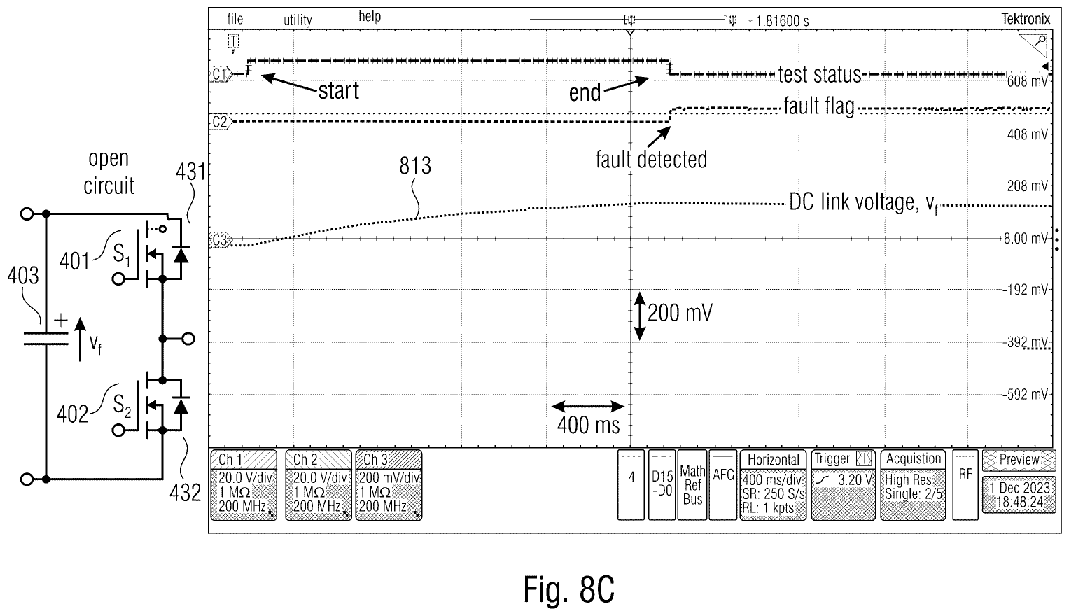

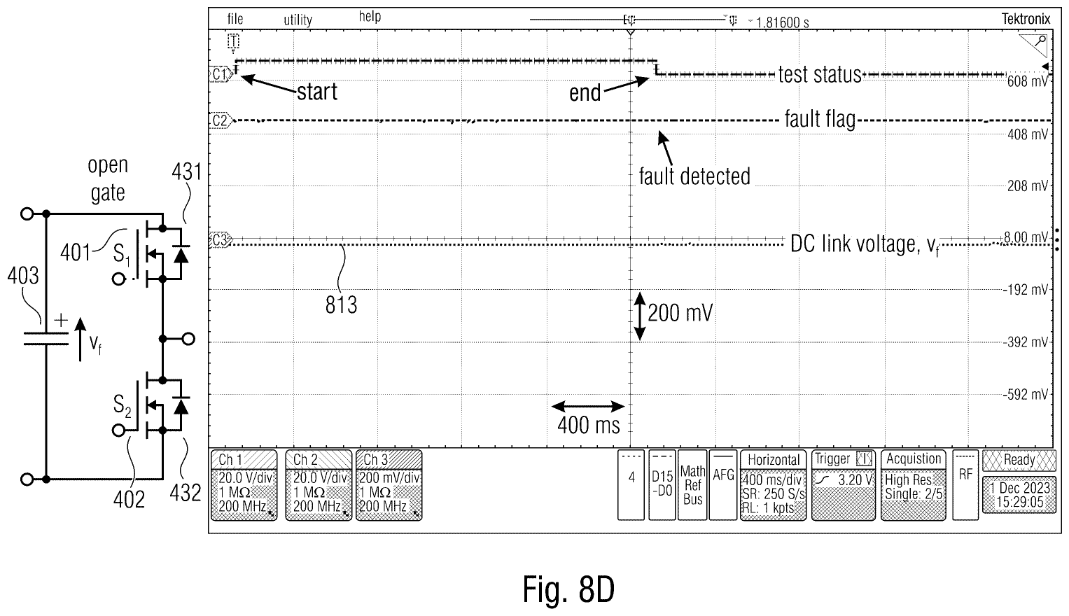

Furthermore, reference is made to FIG. 8. FIG. 8 shows schematic views of circuits in different health states together with examples for corresponding signals. In other words, FIG. 8 shows a device failure detection strategy according to embodiments, applied experimentally to (a) a healthy switching cell showing no fault detection, and a switching cell with a (b) short-circuited, (c) open-circuited, and (d) open-gate MOSFET, with faults detected in these cases.

Referring to FIG. 8, voltage v_{f} of capacitor 403, is indicated with 813 in the respective plots, and may correspond to signal 13 in FIGS. 2 and 3, showing an example for signal 13 associated with different failure modes as discussed in the context of FIG. 4. As shown in FIG. 8 embodiments allow detecting different failure modes of the circuit.

### Further Embodiments

The embodiments described above in detail primarily referred to discriminating healthy/fully functional circuits and non-healthy/faulty circuits by comparing a voltage, which is caused at the terminals of the circuit by complimentarily driving the transistors with the terminals being de-energized or in an open-circuit state, to a threshold voltage, which is set to a value obtained when operating a healthy circuit by complimentarily driving the transistors with the terminals being de-energized or in an open-circuit state. However, the present invention is not limited to a simple determination as to whether a circuit is healthy/functional or non-healthy/faulty, rather, in accordance with other embodiments also a state of degradation of a circuit is considered.

As has been also described above, in accordance with embodiments, the threshold against which the voltage across the capacitor or terminals is to be compared may be set also as a fraction of an expected voltage. Stated differently, when considering a healthy circuit and when driving the respective transistors complementarily with the terminals being de-energized, as described above, a charge transfer from the transistors towards the capacitor causes a certain or expected voltage that is detectable across the terminals. The threshold may be set to a fraction of this expected voltage, like ½ or ⅘ of this expected voltage. For example, by testing various circuits at different degrees of degradation, it may be determined to what degree of degradation a circuit operates reliably. This may be represented by the fraction of the expected voltage so that when setting the threshold to this fraction of the expected voltage, a discrimination between healthy/not excessively degraded and non-healthy/excessively degraded circuits may be performed.

For instance, when setting the threshold to ⅘ of the expected voltage, it is assumed that the circuit operates reliably as long as the voltage detected at the terminal is at least ⅘ of the expected voltage. Otherwise, the circuit is deemed to be degraded beyond a level at which a reliable operation can be assumed or expected.

In accordance with embodiments, the circuit, like the circuit in FIG. 1, may be considered healthy (not degraded beyond a certain level) or non-healthy (degraded beyond a certain level) dependent on a comparison of the voltage measured across the terminal and the threshold set to a fraction of the expected voltage across the terminals. With reference to FIG. 2 and FIG. 3, the process for determining the circuit to be healthy/non-healthy is now described. As is shown in FIG. 2 and FIG. 3, the enable signal 9 is set to a high level so that the gate drive signals 5, 6 to the devices/transistors 1, 2 are activated. The threshold 14, in accordance with this embodiment, is set to a fractional value of the above-mentioned expected voltage at the terminals of a healthy system (when being operated by complementarily driving the transistors with the terminal being de-energized). As is shown in FIG. 2, if the cell is healthy, a negative value of the voltage 13 (the voltage generated by complimentarily driving the transistors with the terminals being de-energized) which is lower than the threshold 14 is measured. Hence, the threshold comparison output 16 becomes low. The delay T_{d} in the delayed enable signal 18 may be adjusted or set such that the delayed signal 18 becomes high only after the comparison output 16 becomes low. Consequently, the output 20, which may now be referred to as a degradation indicator output 20, remains low indicating a healthy switching cell, i.e. a switching cell that has not yet degraded beyond a certain level.

On the other hand, as it is shown in FIG. 3, if the cell deteriorated or degraded beyond the certain level of degradation, a negative value of the voltage 13 which is higher than the threshold 14 or a non-negative value of the voltage 13 is measured after the gate driver enable signal is activated. Hence, the threshold comparison output 16 remains high so that, when the delayed gate drive enable signal 18 becomes high, the degradation indicator output 20 also becomes high indicating a degradation of the circuit beyond a certain degree, for example the degradation of one, some or all of the circuit elements, especially of the active elements, like the transistors 1 and 2 of the circuit.

The advantage of this embodiment is that, other than in the first embodiment discriminating only healthy (fully functional) and non-healthy (non-functional) circuits, is allows for monitoring the circuits and for maintaining circuits in an overall system as long as a degree of degradation does not go beyond a certain, predefined level thereby avoiding the need to replace circuits which are no longer fully functional but still, given the degree of degradation, operate reliably. Thus, embodiments also provides a method and apparatus for monitoring a degradation of circuit elements, like insulated-gate power semiconductor devices in a power electronic converter, while the converter is de-energized.

In the conventional technology, several approaches for detecting a deterioration of circuit elements are known.
(1) A first approach relates to a method of detecting a deterioration of semiconductor elements by keeping a voltage across a semiconductor device constant at a preset value by varying the control voltage of the semiconductor device, and in case the device is not able to maintain the voltage at a constant level this is inferred as a degradation in the device.
   This approach is disadvantageous as there is no possibility to detect a degradation of device parameters that affect the dynamic performance of a device which limits the capability of such an approach. Further, the test requires a specialized circuit with a variable control voltage and, hence, involves additional complexity and cost. Further, the test requires the device to be mounted in the testing site and hence cannot be performed in situ on existing systems.
(2) A second approach relates to a diagnostic device and method for establishing a degradation state of an electrical connection in a power semiconductor device. A voltage across a semiconductor device is measured under various current values and stored as a calibration reference. Subsequently, the voltages across the device are measured under the exact same currents and compared to the calibrated values so that a deviation in the measured and calibrated values is attributed to a device degradation.
   This approach is disadvantageous as there is no possibility to detect the degradation of the device parameters that affect the dynamic performance thereof which limits the applicability of this method. Also, current and voltage measurement arrangements as well as synchronization mechanisms for these arrangements are necessary thereby increasing the cost and complexity of the testing.
(3) A third approach relates to determining a deterioration of a power semiconductor module using a temperature which is inferred from a value of a temperature-dependent device parameter. This is compared to an actual measured temperature and a deviation is inferred as a degradation of the device.
   This approach is disadvantageous as, in case the device parameter is dependent on quantities other than the temperature, the variation of these quantities may confound the degradation of inference and produce unreliable results. Further, the approach requires a temperature measurement involving additional cost and complexity due to the required sensors.
(4) A fourth approach relates to detecting a degradation of semiconductor devices by measuring a number of characteristics and comparing them to reference or calibration values so as to infer a degradation of the device dependent on the detected deviations. This approach is disadvantageous as it requires a large number of additional sensor circuits thereby increasing the complexity and cost of the measurement system. Moreover, the method cannot be implemented on existing systems due to the required modifications to the circuits.
(5) A firth approach relates to detecting aging deteriorations of power electronics equipment by passing a sinusoidal current through a semiconductor device under test. The resulting temperature rise of the device is recorded. The amplitude of the temperature variation is compared to the reference amplitude to infer a device degradation.
   This approach is disadvantageous because degradations is not directly affecting conduction loss cannot be detected through this method. Further, additional circuitry and sensors are required for applying the sinusoidal current excitation and for measuring the amplitude of the temperature variation, thereby increasing complexity and cost. Also, the method requires the device to be placed in a test setup and, hence, cannot be performed in situ.

Contrary to the above-summarized known approaches, the inventive approach, in accordance with the embodiments allowing for determining a degradation of a circuit, is advantageous as any mode of degradation that affects the device parameters directly and the measured voltage indirectly can be detected, i.e., there is no limit to detecting a degradation of a specific type as it is present in the above-described conventional technology approaches (1), (2), (3) and (5).

Further, the inventive approach is non-invasive since it does not require any access to any additional signals within the overall system, like the power converter. The measured voltage used for the detection is available from a voltage sensor connected to a power converter and even if such a sensor is not present, an external sensor may be connected to the converter terminals and does not require access to the circuit or the power converter. Thus, the inventive approach is less cost intensive and straightforward to implement, in contrast to the above-described conventional technology approaches (1) to (5) requiring an access or an invasion of the semiconductor device gate drive circuit as well as additional sensing and test arrangements.

Also, embodiments of the inventive approach make use of minimal components, e.g., a voltage threshold generation, an AND gate, a time-delay block and a comparator, i.e., require only a single prior measurement, namely the voltage of a healthy cell, in order to set the voltage threshold during an initial calibration. On the other hand, the above-described conventional technology approaches, especially approaches (2) and (5), require a large number of additional measurements and calibrations.

In accordance with embodiments, the inventive approach may be applied to any power converter system having a large number of modular switching cells and for which an early detection of a degradation, for example, during a periodic maintenance, is desired for preventing failures. Examples for such systems include modular high-voltage DC-AC power converters for medium-voltage drives and high-voltage direct-current transmissions, solid-state transformers and DC energy hubs for smart distribution systems, and two-level voltage-source inverter applications as used, e.g., in grid-connected and solar micro-inverter applications.

### Implementation Alternatives:

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus. Some or all of the method steps may be executed by (or using) a hardware apparatus, like for example, a microprocessor, a programmable computer or an electronic circuit. In some embodiments, one or more of the most important method steps may be executed by such an apparatus.

Depending on certain implementation requirements, embodiments of the invention, in particular functionalities for an evaluation of the measured entities for obtaining the health information and/or for providing control signals, can be implemented in hardware or in software. The implementation can be performed using a digital storage medium, for example a floppy disk, a DVD, a Blu-Ray, a CD, a ROM, a PROM, an EPROM, an EEPROM or a FLASH memory, having electronically readable control signals stored thereon, which cooperate (or are capable of cooperating) with a programmable computer system such that the respective method is performed. Therefore, the digital storage medium may be computer readable.

Some embodiments according to the invention comprise a data carrier having electronically readable control signals, which are capable of cooperating with a programmable computer system, such that one of the methods described herein is performed.

Generally, embodiments of the present invention can be implemented as a computer program product with a program code, the program code being operative for performing one of the methods when the computer program product runs on a computer. The program code may for example be stored on a machine-readable carrier.

Other embodiments comprise the computer program for performing one of the methods described herein, stored on a machine-readable carrier.

In other words, an embodiment of the inventive method is, therefore, a computer program having a program code for performing one of the methods described herein, when the computer program runs on a computer.

A further embodiment of the inventive methods is, therefore, a data carrier (or a digital storage medium, or a computer-readable medium) comprising, recorded thereon, the computer program for performing one of the methods described herein. The data carrier, the digital storage medium or the recorded medium are typically tangible and/or non-transitionary.

A further embodiment of the inventive method is, therefore, a data stream or a sequence of signals representing the computer program for performing one of the methods described herein. The data stream or the sequence of signals may for example be configured to be transferred via a data communication connection, for example via the Internet.

A further embodiment comprises a processing means, for example a computer, or a programmable logic device, configured to or adapted to perform one of the methods described herein.

A further embodiment comprises a computer having installed thereon the computer program for performing one of the methods described herein.

A further embodiment according to the invention comprises an apparatus or a system configured to transfer (for example, electronically or optically) a computer program for performing one of the methods described herein to a receiver. The receiver may, for example, be a computer, a mobile device, a memory device or the like. The apparatus or system may, for example, comprise a file server for transferring the computer program to the receiver.

In some embodiments, a programmable logic device (for example a field programmable gate array) may be used to perform some or all of the functionalities of the methods described herein. In some embodiments, a field programmable gate array may cooperate with a microprocessor in order to perform one of the methods described herein. Generally, the methods are performed by any hardware apparatus.

The apparatus described herein may be implemented using a hardware apparatus, or using a computer, or using a combination of a hardware apparatus and a computer.

The apparatus described herein, or any components of the apparatus described herein, may be implemented at least partially in hardware and/or in software.

The methods described herein may be performed using a hardware apparatus, or using a computer, or using a combination of a hardware apparatus and a computer.

The methods described herein, or any components of the apparatus described herein, may be performed at least partially by hardware and/or by software.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

1. A method for testing a circuit, the circuit comprising two terminals, a capacitor coupled between the two terminals and a plurality of serially connected transistors coupled in parallel with the capacitor between the two terminals, the method comprising:
complementarily driving the plurality of serially connected transistors with the two terminals being in a de-energized state,
detecting an electrical quantity of the circuit, and
determining, using the electrical quantity, whether or not the circuit is healthy.

2. The method of claim 1, wherein detecting the electrical quantity comprises one or more of the following:
detecting a voltage across the capacitor, e.g., by connecting a voltage measurement device across the two terminals;
detecting a voltage across the terminals;
detecting a voltage across one or more individual elements in the circuit.

3. The method of claim 1, wherein determining whether or not the circuit is healthy comprises:
comparing a voltage to a threshold voltage, and
determining, using the comparison, whether or not the circuit is healthy.

4. The method of claim 3, wherein the threshold voltage is determined using one or more properties of the transistors, e.g., a forward voltage of a diode associated with the transistors.

5. The method of claim 4, wherein
when the circuitry is healthy, complementarily driving the plurality of serially connected transistors with the two terminals being in a de-energized state causes an expected voltage across the two terminals, and
the threshold voltage comprises a value equal to the expected voltage so as to allow discriminating, by measuring the voltage across the two terminals, healthy circuits and faulty circuits.

6. The method of claim 3, wherein the threshold voltage is determined as a fraction of an expected voltage across the capacitor, e.g., ½ or ⅘ of the expected voltage across the capacitor.

7. The method of claim 6, wherein
when the circuitry is healthy, complementarily driving the plurality of serially connected transistors with the two terminals being in a de-energized state causes the expected voltage across the two terminals, and
the threshold voltage comprises a value equal to the fraction of the expected voltage so as to allow discriminating, by measuring the voltage across the two terminals, healthy circuits, which have degraded by less than a certain degree, and non-healthy circuits, which have degraded by the certain degree or by more than the certain degree.

8. The method of claim 3, wherein
the circuit is determined not healthy or faulty if a comparison of the voltage and the threshold voltage yields a comparison signal comprising a first logical level, e.g., a high level,
the circuit is determined healthy if the comparison of the voltage and the threshold voltage yields the comparison signal comprising a second logical level, e.g., a low level.

9. The method of claim 8, further comprising:
logically combining the comparison signal and a gate driver enable signal, which causes the transistors to be driven and which comprises the first logical level,
if the comparison signal and the gate driver enable signal comprise different logical levels, indicating that the circuit is healthy and
if the comparison signal and the gate driver enable signal comprise the same logical levels, indicating that the circuit is not healthy or faulty.

10. The method of claim 1, wherein driving the plurality of serially connected transistors comprises applying complementary gate driver signals to respective control terminals of the serially connected transistors for complementarily turning on and off the transistors.

11. The method of claim 10, wherein driving the plurality of serially connected transistors comprises activating, using the gate driver enable signal, a plurality of gate drivers, which are coupled to the respective transistors.

12. The method of claim 1, wherein the plurality of serially connected transistors comprises an insulated-gate bipolar transistor, IGBT, and/or a metal-oxide-semiconductor field-effect transistor, MOSFET.

13. The method of claim 12, wherein the plurality of serially connected transistors comprises two serially connected IGBTs or two serially connected MOSFETs coupled in parallel with the capacitor between the two terminals.

14. An apparatus for testing a circuit, the circuit comprising two terminals, a capacitor coupled between the two terminals and a plurality of serially connected transistors coupled in parallel with the capacitor between the two terminals, the apparatus comprising:
a driver circuit connectable to the plurality of serially connected transistors for complementarily driving the plurality of serially connected transistors of the circuit,
a measurement device for detecting an electrical quantity of the circuit with the two terminals being in a de-energized state and with the plurality of serially connected transistors of the circuit being driven complementarily, and
a signal processing circuit coupled to the measurement device for determining, using the electrical quantity, whether or not the circuit is healthy.

15. The apparatus of claim 14,
wherein the measurement device is configured to measure a voltage in order to detect the electrical quantity, and
wherein the voltage is at least one of
a voltage across the terminals,
a voltage across the capacitor,
a voltage across one or more individual elements in the circuit.

16. The apparatus of claim 15, wherein
the signal processing circuit comprises a comparator for comparing the voltage to a threshold voltage,
the signal processing circuit is configured to output a first signal indicating the circuit to be not healthy or faulty if the comparator outputs a comparison signal comprising a first logical level, e.g., a high level, and
the signal processing circuit is configured to output a second signal indicating the circuit to be healthy if the comparator outputs a comparison signal comprising a second logical level, e.g., a low level.

17. The apparatus of claim 16, wherein
when the circuitry is healthy, complementarily driving the plurality of serially connected transistors with the two terminals being in a de-energized state causes an expected voltage across the two terminals, and
the threshold voltage comprises a value
equal to the expected voltage so as to allow discriminating, by measuring the voltage across the two terminals, healthy circuits and faulty circuits, or
equal to a fraction of the expected voltage so as to allow discriminating, by measuring the voltage across the two terminals, healthy circuits, which have degraded by less than a certain degree, and non-healthy circuits, which have degraded by the certain degree or by more than the certain degree.

18. The apparatus of claim 16, wherein
the signal processing circuit further comprises a logic gate for logically combining the comparison signal of the comparator and a gate driver enable signal, which causes the transistors to be driven and which comprises the first logical level,
the logic gate is configured to output the first signal if the comparison signal and the gate driver enable signal comprise the same logical levels, and
the logic gate is configured to output the second signal if the comparison signal and the gate driver enable signal comprise different logical levels.

19. The apparatus of claim 18, wherein the logic gate comprises an AND gate.

20. The apparatus of claim 14, wherein the driver circuit comprises respective gate drivers connectable to the transistors for applying complementary gate driver signals to respective control terminals of the serially connected transistors for complementarily turning on and off the transistors.
